(19) United States
(12) Patent Application Publication
(10) Pub. No.: US 2019/0051667 A1
(43) Pub. Date: Feb. 14, 2019

(54) AN ARRAY SUBSTRATE AND A MANUFACTURING METHOD THEREOF, A DISPLAY PANEL, AS WELL AS A DISPLAY DEVICE

(71) Applicants: Boe Technology Group Co., Ltd., Beijing (CN); HEFEI XINSHENG OPTOELECTRONICS TECHNOLOGY CO., LTD, Anhui (CN)

(72) Inventors: Zhenfei Cai, Beijing (CN); Xingxing Song, Beijing (CN)

(21) Appl. No.: 15/513,970

(22) PCT Filed: Apr. 15, 2016
(86) PCT No.: PCT/CN2016/079355

§ 371 Date: Mar. 23, 2017

(30) Foreign Application Priority Data
Jun. 26, 2015 (CN) 201510369169.9

(51) Int. Cl. H01L 27/12; G09G 3/20

(52) U.S. Cl. CPC H01L 27/124; G09G 3/20; G02F 1/136286; G09G 2300/0426; H01L 27/127

(57) ABSTRACT

The present disclosure discloses an array substrate and a manufacturing method thereof, a display panel, as well as a display device. The array substrate comprises common electrodes and common electrode lines. The common electrode lines are parallel to the data lines. The data lines and the common electrode lines are distributed alternately between columns of sub-pixel units. The common electrode lines are in direct contact and electrically connected with the common electrodes. Each data line is connected with two columns of sub-pixel units adjacent to the data line. One gate line is distributed at each side of each row of sub-pixel units, and two gate lines are distributed between two adjacent rows of sub-pixel units. Two adjacent sub-pixel units in each row connected to a same data line are respectively connected with different gate lines distributed at two sides of the row of sub-pixel units.

### TECHNICAL FIELD

The present disclosure relates to the field of display, particularly to an array substrate and a manufacturing method thereof, a display panel, as well as a display device.

### BACKGROUND

The thin film transistor liquid crystal display (TFT-LCD) is the commonly used panel display currently. TFT-LCD has been studied and applied widely by right of its advantages such as low voltage, low power consumption, being suitable for circuit integration, and being portable etc.

A conventional high-aperture-ratio, high-advanced super dimension switch (HADS) mode thin film transistor (TFT) substrate is shown in FIG. 1. The HADS mode TFT substrate has common electrode lines 11 and gate lines 12 extending along the horizontal direction, as well as data lines 13 extending along the vertical direction. A drain of the TFT 15 is connected with a first indium tin oxide (ITO) layer (not shown in the figure) for providing a pixel electrode signal. A second ITO layer (not shown in the figure) is connected with the common electrode line 11 through via holes 14 for applying a common electrode signal.

The common electrode lines 11 in FIG. 1 are manufactured using the metal in the same as the gate lines 12. Hence, the resistance of the common electrode lines 11 is much smaller than the resistance of the second ITO layer. Since the resistance is small, the capability of transmitting electric signals is strong, thereby being capable of improving uniformity of the common electrode signal. However, such a design has to design via holes 14 separately so as to be connected with the second ITO layer. The design of via holes 14 would occupy the display area within the pixel, which may reduce the aperture ratio of the pixel on the TFT substrate, and is unfavorable for improvement of the product performance. In addition, although such a design improves uniformity of the common electrode signal to some extent, the common electrode lines 11 and the common electrodes (i.e., the second ITO layer) are connected through via holes 14, which belong to point contact. In this case, the contact area is small, and the contact resistance is relatively large. Hence, the uniformity of the common electrode signal is still relatively poor. Because the contact resistance is relatively large, it is generally required to design a via hole 14 every four pixels or for each pixel. The design of via holes further reduces the aperture ratio of the pixel.

To sum up, the existing HADS mode TFT substrate pixel has a relatively low aperture ratio, and the uniformity of the common electrode signal is relatively poor.

### SUMMARY

Embodiments of the present disclosure provide an array substrate and a manufacturing method thereof, a display panel, as well as a display device, for improving uniformity of the common electrode signal and increasing the aperture ratio of the pixel.

An aspect of the present disclosure provides an array substrate. The array substrate comprises a plurality of gate lines and a plurality of data lines, a plurality of sub-pixel units arranged in array, and thin film transistors in one-to-one correspondence with the plurality of sub-pixel units. The array substrate further comprises common electrodes and common electrode lines.

The common electrode lines are parallel to the data lines. The data lines and the common electrode lines are distributed alternately between columns of sub-pixel units. The common electrode lines are in direct contact and electrically connected with the common electrodes. Each data line is connected with two columns of sub-pixel units adjacent to the data line.

One gate line is distributed at each side of each row of sub-pixel units, and two gate lines are distributed between two adjacent rows of sub-pixel units. Two adjacent sub-pixel units in each row connected to a same data line are respectively connected with different gate lines distributed at two sides of the row of sub-pixel units.

Compared to the existing approach where the common electrodes and the common electrode lines are electrically connected through via holes, in embodiments of the present disclosure, the common electrode lines are in direct contact and electrically connected with the common electrodes. In this case, the contact area is relatively large, and the contact resistance is relatively small. Hence, the uniformity of the common electrode signal can be improved. In addition, compared to the existing approach where via holes have to be arranged when the common electrodes are connected with the common electrode lines, in embodiments of the present disclosure, the common electrodes and the common electrode lines are in direct contact and are electrically connected. Therefore, there is no need to arrange via holes, and thus, the aperture ratio of the pixel can be increased.

In one embodiment, the common electrode lines and the data lines are arranged in a same layer.

In one embodiment, the common electrode lines and the data lines are distributed in a manner that in the row direction the odd lines are data lines and the even lines are common electrode lines.

Alternatively, in another embodiment, the common electrode lines and the data lines are distributed in a manner that in the row direction the even lines are data lines and the odd lines are common electrode lines.

In one embodiment, the array substrate comprises a first insulating layer. The first insulating layer is located between the gate lines and the common electrode lines. The common electrodes are located on the common electrode lines, and are in direct contact and electrically connected with the common electrode lines.

In one embodiment, the array substrate comprises pixel electrodes. The pixel electrodes are located above the common electrodes.

In one embodiment, the array substrate comprises a second insulating layer. The second insulating layer is located between the common electrodes and the pixel electrodes.

Another aspect of the present disclosure provides a display panel. The display panel comprises an array substrate provided by any of the above embodiments.

Another aspect of the present disclosure provides a display device. The display device comprises the above display panel.

Another aspect of the present disclosure provides a method of manufacturing an array substrate. The method comprises the following steps:

manufacturing gates and gate lines on a base substrate, wherein one gate line is distributed at each side of each row of sub-pixel units, and two gate lines are distributed between two adjacent rows of sub-pixel units;

manufacturing a first insulating layer and a semiconductor active layer successively;

manufacturing sources, drains, data lines and common electrode lines, wherein the common electrode lines are parallel to the data lines, the common electrode lines and the data lines are distributed alternately between columns of sub-pixel units, each data line is connected with two columns of sub-pixel units adjacent to the data line, two adjacent sub-pixel units in each row connected to a same data line are respectively connected with different gate lines distributed at two sides of the row of sub-pixel units;

manufacturing common electrodes, wherein the common electrodes are in direct contact and electrically connected with the common electrode lines;

manufacturing a second insulating layer and via holes that penetrate the second insulating layer;

manufacturing pixel electrodes, wherein the pixel electrodes are electrically connected with the sources or the drains through the via holes.

In one embodiment, the step of manufacturing the common electrodes comprises the following sub-steps:

depositing a transparent electrically conductive layer;

coating photoresist on the transparent electrically conductive layer, performing exposure and development on the photoresist, and leaving photoresist of the common electrode lines and pixel areas;

removing the exposed transparent electrically conductive layer through etching, and removing the remaining photoresist to form common electrodes.

### BRIEF DESCRIPTION OF THE DRAWINGS

FIG. 1 is a schematic view for a plane structure of an existing array substrate;

FIG. 2 is a schematic view for a plane structure of an array substrate provided by embodiments of the present disclosure;

FIG. 3 is a schematic view for a plane structure of another array substrate provided by embodiments of the present disclosure;

FIG. 4 is a schematic view for a sectional structure along AA1 direction in FIG. 2 or FIG. 3;

FIG. 5 is a schematic view for a sectional structure along BB1 direction in FIG. 2 or FIG. 3; and

FIG. 6 is a flow chart for a method of manufacturing an array substrate provided by embodiments of the present disclosure.

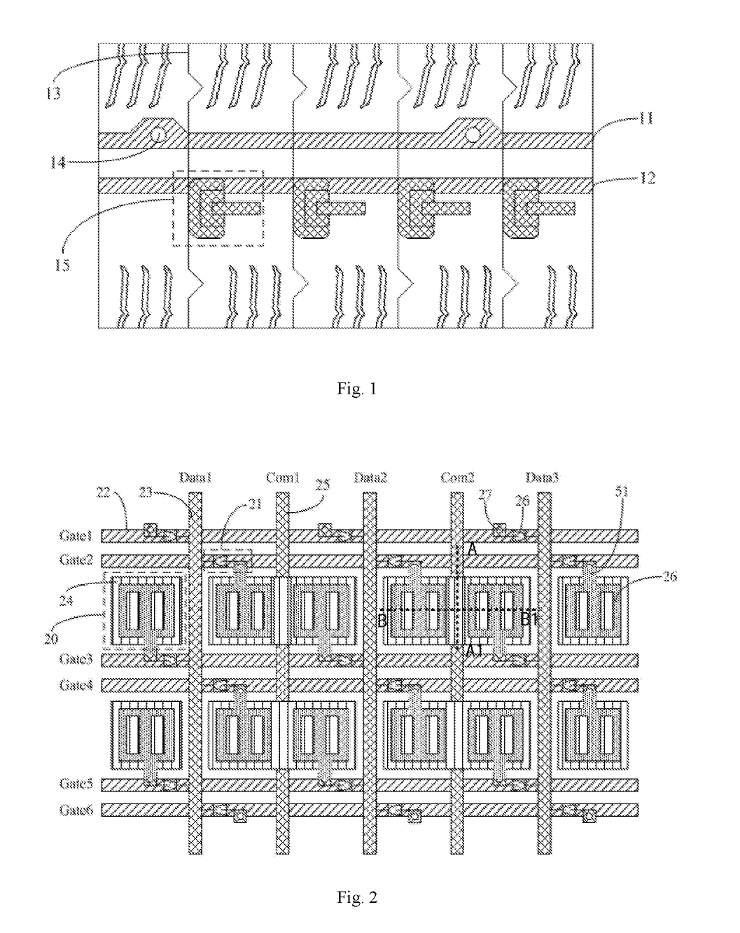

### DETAILED DESCRIPTION

Embodiments of the present disclosure provide an array substrate and a manufacturing method thereof, a display panel, as well as a display device, for improving uniformity of the common electrode signal and increasing the aperture ratio of the pixel.

In order to enable objects, technical solutions and advantages of the present disclosure to be clearer, the present disclosure will be described in more details with reference to the drawings below. Apparently, the embodiments described are only a part but not all of those embodiments of the present disclosure. All other embodiments obtained by the ordinary skilled person in the art without paying any creative work based on the embodiments in the present disclosure fall within the protection scope of the present disclosure.

The thickness, size and shape of respective films in the drawings do not reflect the real proportions of the respective films, which only aims to schematically explaining contents of the present disclosure.

Next, the array substrate provided by embodiments of the present disclosure will be introduced in detail with reference to the drawings.

As shown in FIG. 2, embodiments of the present disclosure provide an array substrate. The array substrate may comprise a plurality of gate lines 22, a plurality of data lines 23, a plurality of sub-pixel units 20 arranged in array, thin film transistors 21 in one-to-one correspondence with the plurality of sub-pixel units 20, as well as common electrodes 24 and common electrode lines 25.

The common electrode lines 25 may be parallel to the data lines 23. The data lines 23 and the common electrode lines 25 can be distributed alternately between columns of sub-pixel units 20. The common electrode lines 25 can be in direct contact and electrically connected with the common electrodes 24. Each data line 23 can be connected with two columns of sub-pixel units 20 adjacent to the data line 23. The common electrode lines 25 and the data lines 23 can also be arranged in a same layer.

One gate line 22 can be distributed at each side of each row of sub-pixel units 20, and two gate lines can be distributed between two adjacent rows of sub-pixel units. Besides, two adjacent sub-pixel units 20 in each row connected to a same data line 23 can be respectively connected with different gate lines 22 distributed at two sides of the row of sub-pixel units 20.

In embodiments of the present disclosure, the common electrode lines 25 and the data lines 23 can be distributed in a manner that in the row direction, the odd lines are data lines and the even lines are common electrode lines. As shown in FIG. 2, the first column is a data line Data1, the second column is a common electrode line Com1, the third column is a data line Data2, the fourth column is a common electrode line Com2, and the fifth column is a data line Data3.

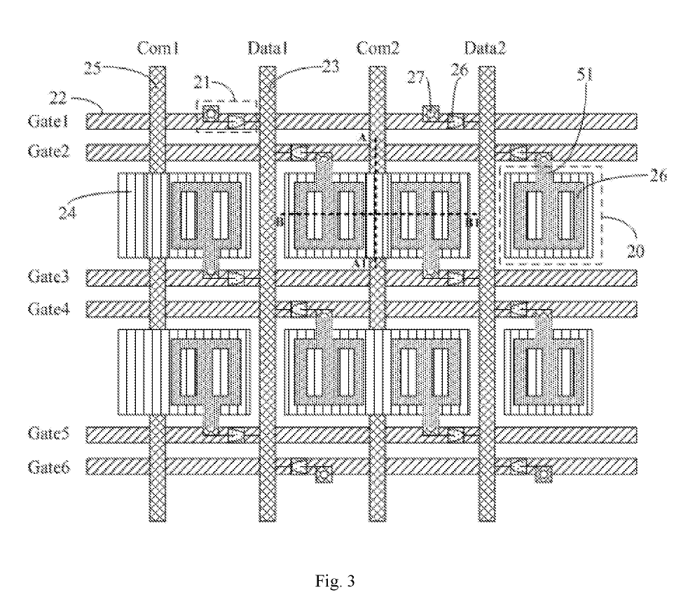

In embodiments of the present disclosure, the common electrode lines 25 and the data lines 23 can also be distributed in a manner that in the row direction, the even lines are data lines and the odd lines are common electrode lines. As shown in FIG. 3, the first column is a common electrode line Com1, the second column is a data line Data1, the third column is a common electrode line Com2, and the fourth column is a data line Data2.

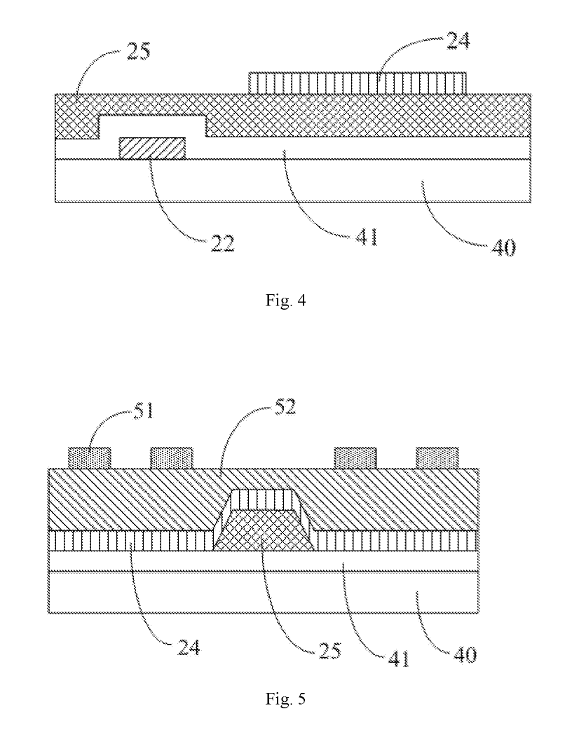

The sectional view along the AA1 direction in FIG. 2 or FIG. 3 is shown in FIG. 4. The array substrate may further comprise a first insulating layer 41. The first insulating layer 41 can be located between the gate lines 22 and the common electrode lines 25. The common electrodes 24 may be located on the common electrode lines 25, and in direct contact and electrically connected with the common electrode lines 25. Specifically, the gate lines 22 in embodiments of the present disclosure can also be located on a base substrate 40.

The sectional view along the BB1 direction in FIG. 2 or FIG. 3 is shown in FIG. 5. In this case, the array substrate may further comprise pixel electrodes 51 and a second insulating layer 52. The pixel electrodes 51 may be located above the common electrodes 24. The second insulating layer 52 may be located between the common electrodes 24 and the pixel electrodes 51. As an example, the pixel electrodes 51 in specific embodiments of the present disclosure may be slit electrodes.

From FIG. 4 and FIG. 5 it can be seen that in embodiments of the present disclosure, the common electrodes 24 and the common electrode lines 25 are in direct contact and electrically connected. In this case, the contact area is the whole common electrode line 25. Compared to the existing approach where the common electrodes and the common electrode lines are connected through via holes, the contact area of the common electrodes and the common electrode lines in embodiments of the present application is relatively large, and the contact resistance is relatively low. Hence, the uniformity of the common electrode signal can be improved.

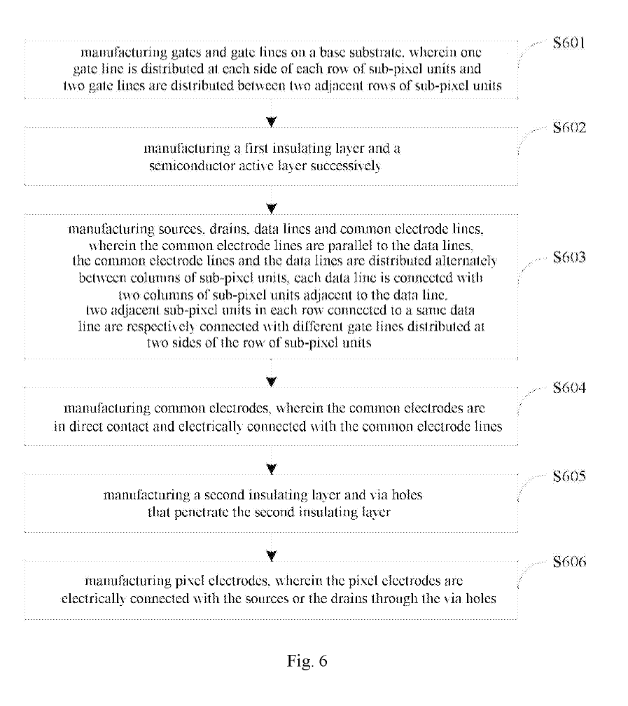

As shown in FIG. 6, embodiments of the present disclosure further provide a method of manufacturing an array substrate. The method may specifically comprise the following steps:

S601, manufacturing gates and gate lines on a base substrate, wherein one gate line is distributed at each side of each row of sub-pixel units, and two gate lines are distributed between two adjacent rows of sub-pixel units;

S602, manufacturing a first insulating layer and a semiconductor active layer successively;

S603, manufacturing sources, drains, data lines and common electrode lines, wherein the common electrode lines are parallel to the data lines, the common electrode lines and the data lines are distributed alternately between columns of sub-pixel units, each data line is connected with two columns of sub-pixel units adjacent to the data line, two adjacent sub-pixel units in each row connected to a same data line are respectively connected with different gate lines distributed at two sides of the row of sub-pixel units;

S604, manufacturing common electrodes, wherein the common electrodes are in direct contact and electrically connected with the common electrode lines;

S605, manufacturing a second insulating layer and via holes that penetrate the second insulating layer;

S606, manufacturing pixel electrodes, wherein the pixel electrodes are electrically connected with the sources or the drains through the via holes.

Specifically, referring to FIG. 2 to FIG. 5, firstly, a metal film is deposited on the base substrate. Then, a patterning process is performed on the metal film to form gates (not shown in the figure) and gate lines 22. The patterning process can include part or all of processes such as coating, exposing, developing, etching and removing the photoresist. Specifically, the base substrate can be a glass substrate. Certainly, during a process of actual production, the base substrate can also be a substrate such as a ceramic substrate. The metal film deposited on the base substrate is a monolayer film of metals such as Mo, Al, or a composite film consisting of various metals. Materials suitable for the metal film will not be limited specifically in embodiments of the present disclosure.

Next, the first insulating layer 41 and the semiconductor active layer 26 can be manufactured by patterning process on the base substrate on which the above step has been performed. Materials suitable for the first insulating layer can be a monolayer film of silicon oxide (SiO2) or silicon nitride (SIN), or can be a composite film consisting of SiO2 and SiN. Materials suitable for the first insulating layer will not be limited specifically in embodiments of the present disclosure. The process of manufacturing the first insulating layer and the semiconductor active layer can be same as that in the existing approach, which will not be repeated here.

Next, a metal film is deposited on the base substrate on which the above step has been performed. Then, a patterning process is performed on the metal film to form sources (not shown in the figure), drains (not shown in the figure), data lines 22 and common electrode lines 25. The common electrode lines 25 can be parallel to the data lines 23. The common electrode lines 25 and the data lines 23 can be distributed alternately between columns of sub-pixel units 20. In embodiments of the present disclosure, the data lines 23 and the common electrode lines 25 can be manufactured only by one patterning process. Therefore, there is no need to add any extra production process, which is more simple and convenient for actual production. Material suitable for the metal film deposited on the base substrate in this step can be same as materials suitable for the metal film deposited when manufacturing the gates and the gate lines. Certainly, in actual production, material suitable for the metal film deposited in this step can also be different from materials suitable for the metal film deposited when manufacturing the gates and the gate lines. Materials suitable for the metal film deposited in this step will not be limited specifically in embodiments of the present disclosure.

Next, a transparent electrically conductive layer can be deposited on the base substrate on which the above step has been performed. The deposited transparent electrically conductive layer can be an indium tin oxide (ITO) film, or can be an indium zinc oxide (IZO) film, or can be a composite film consisting of ITO and IZO. Materials suitable for the transparent electrically conductive layer will not be limited specifically in embodiments of the present disclosure. Thereafter, photoresist is coated on the transparent electrically conductive layer, and then the photoresist is exposed and developed, leaving photoresist of the common electrode lines and pixel areas behind and photoresist of other areas removed. The areas with photoresist removed expose the transparent electrically conductive layer. Thereafter, the exposed transparent electrically conductive layer is removed by etching, preferably by wet-etching. In this case, only the transparent electrically conductive layer located above the common electrode lines and the pixel areas is reserved, while the transparent electrically conductive layer of other areas is removed. Finally, the remaining photoresist is removed to form the common electrodes 24 above the common electrode lines and the pixel areas. The common electrodes 24 are in direct contact and electrically connected with the common electrode lines 25.

Next, a second insulating layer 52 and via holes 27 that penetrate the second insulating layer 52 can be manufactured through patterning process on the base substrate on which the above step has been performed. Materials suitable for the second insulating layer 52 can be same as materials suitable for the first insulating layer 41. Certainly, in actual production, materials suitable for the second insulating layer can also be different from materials suitable for the first insulating layer. Materials suitable for the second insulating layer will not be limited specifically in embodiments of the present disclosure. The process of manufacturing the second insulating layer and the via holes that penetrate the second insulating layer 52 in embodiments of the present disclosure can be same as that in the existing approach, which will not be repeated here.

Next, a transparent electrically conductive layer can be deposited on the base substrate on which the above step has been performed. Thereafter, a patterning process is performed on the transparent electrically conductive layer to form pixel electrodes 51. The pixel electrodes 51 can be electrically connected with the sources or the drains through the via holes 27. Materials suitable for the transparent electrically conductive layer that forms the pixel electrodes can be same as materials suitable for the transparent electrically conductive layer that forms the common electrodes. Certainly, in actual production, materials suitable for the transparent electrically conductive layer that forms the pixel electrodes can also be different from materials suitable for the transparent electrically conductive layer that forms the common electrodes. Materials suitable for the transparent electrically conductive layer that forms the pixel electrodes will not be limited specifically in embodiments of the present disclosure.

To sum up, embodiments of the present disclosure provide an array substrate and a manufacturing method thereof, a display panel, as well as a display device. The array substrate comprises a plurality of gate lines and a plurality of data lines, a plurality of sub-pixel units arranged in array, and thin film transistors in one-to-one correspondence with the plurality of sub-pixel units. The array substrate further comprises common electrodes and common electrode lines. The common electrode lines are parallel to the data lines. The data lines and the common electrode lines are distributed alternately between columns of sub-pixel units. The common electrode lines are in direct contact and electrically connected with the common electrodes. Each data line is connected with two columns of sub-pixel units adjacent to the data line. One gate line is distributed at each side of each row of sub-pixel units and two gate lines are distributed between two adjacent rows of sub-pixel units. Two adjacent sub-pixel units in each row connected to a same data line are respectively connected with different gate lines distributed at two sides of the row of sub-pixel units. Compared to the existing approach where the common electrodes and the common electrode lines are electrically connected through via holes, in embodiments of the present disclosure, the common electrode lines are in direct contact and electrically connected with the common electrodes. The contact area is relatively large, and the contact resistance is relatively small. Hence, the uniformity of the common electrode signal can be improved. In addition, compared to the existing approach where via holes have to be arranged when the common electrodes are connected with the common electrode lines, in embodiments of the present disclosure, the common electrodes and the common electrode lines are in direct contact and are electrically connected. Therefore, there is no need to arrange via holes, and thus the aperture ratio of the pixel can be increased.

Apparently, the skilled person in the art can make various modifications and variations to embodiments of the present disclosure without departing from the spirit and the scope of the present disclosure. In this way, provided that these modifications and variations of embodiments of the present disclosure fall within the scopes of the claims of the present disclosure and the equivalent technologies thereof, the present disclosure also intends to encompass these modifications and variations.

1. An array substrate, comprising:
a plurality of gate lines and a plurality of data lines,
a plurality of sub-pixel units arranged in array,
thin film transistors in one-to-one correspondence with the plurality of sub-pixel units, and
common electrodes and common electrode lines;
wherein the common electrode lines are parallel to the data lines, the data lines and the common electrode lines are distributed alternately between columns of sub-pixel units, the common electrode lines are in direct contact and electrically connected with the common electrodes, each data line is connected with two columns of sub-pixel units adjacent to the data line;
one gate line is distributed at each side of each row of sub-pixel units and two gate lines are distributed between two adjacent rows of sub-pixel units, two adjacent sub-pixel units in each row connected to a same data line are respectively connected with different gate lines distributed at two sides of the row of sub-pixel units.

2. The array substrate according to claim 1, wherein the common electrode lines and the data lines are arranged in a same layer.

3. The array substrate according to claim 1, wherein the common electrode lines and the data lines are distributed in a manner that in the row direction the odd lines are data lines and the even lines are common electrode lines; or
the common electrode lines and the data lines are distributed in a manner that in the row direction the even lines are data lines and the odd lines are common electrode lines.

4. The array substrate according to claim 1, comprising a first insulating layer,
wherein the first insulating layer is located between the gate lines and the common electrode lines, the common electrodes are located on the common electrode lines, and are in direct contact and electrically connected with the common electrode lines.

5. The array substrate according to claim 1, comprising pixel electrodes, wherein the pixel electrodes are located above the common electrodes.

6. The array substrate according to claim 5, comprising a second insulating layer, wherein the second insulating layer is located between the common electrodes and the pixel electrodes.

7. A display panel, comprising the array substrate as claimed in claim 1.

8. A display device, comprising the display panel as claimed in claim 7.

9. A method of manufacturing an array substrate, comprising:
manufacturing gates and gate lines on a base substrate, wherein one gate line is distributed at each side of each row of sub-pixel units, and two gate lines are distributed between two adjacent rows of sub-pixel units;
manufacturing a first insulating layer and a semiconductor active layer successively;
manufacturing sources, drains, data lines and common electrode lines, wherein the common electrode lines are parallel to the data lines, the common electrode lines and the data lines are distributed alternately between columns of sub-pixel units, each data line is connected with two columns of sub-pixel units adjacent to the data line, two adjacent sub-pixel units in each row connected to a same data line are respectively connected with different gate lines distributed at two sides of the row of sub-pixel units;
manufacturing common electrodes, wherein the common electrodes are in direct contact and electrically connected with the common electrode lines;
manufacturing a second insulating layer and via holes that penetrate the second insulating layer;
manufacturing pixel electrodes, wherein the pixel electrodes are electrically connected with the sources or the drains through the via holes.

10. The method according to claim 9, wherein the step of manufacturing the common electrodes comprises:
depositing a transparent electrically conductive layer;
coating photoresist on the transparent electrically conductive layer, performing exposure and development on the photoresist, and leaving photoresist of the common electrode lines and pixel areas;
removing the exposed transparent electrically conductive layer through etching, and removing the remaining photoresist to form common electrodes.

11. The display panel according to claim 7, wherein the common electrode lines and the data lines are arranged in a same layer.

12. The display panel according to claim 7, wherein the common electrode lines and the data lines are distributed in a manner that in the row direction the odd lines are data lines and the even lines are common electrode lines; or
the common electrode lines and the data lines are distributed in a manner that in the row direction the even lines are data lines and the odd lines are common electrode lines.

13. The display panel according to claim 7, comprising a first insulating layer, wherein the first insulating layer is located between the gate lines and the common electrode lines, the common electrodes are located on the common electrode lines, and are in direct contact and electrically connected with the common electrode lines.

14. The display panel according to claim 7, comprising pixel electrodes, wherein the pixel electrodes are located above the common electrodes.

15. The display panel according to claim 14, comprising a second insulating layer, wherein the second insulating layer is located between the common electrodes and the pixel electrodes.

16. A display device, comprising the display panel as claimed in claim 11.

17. A display device, comprising the display panel as claimed in claim 12.

18. A display device, comprising the display panel as claimed in claim 13.

19. A display device, comprising the display panel as claimed in claim 14.

20. A display device, comprising the display panel as claimed in claim 15.
